(19) United States
(12) Patent Application Publication
(10) Pub. No.: US 2022/0269069 A1
(43) Pub. Date: Aug. 25, 2022

(54) TECHNIQUE TO DETECT THE ROTATIONAL DIRECTION OF RESONANT MEMS MIRRORS DRIVEN BY PARAMETRIC EXCITATION

(71) Applicant: GOOGLE LLC, Mountain View, CA (US)

(72) Inventor: Sangtak Park, Kitchener (CA)

(21) Appl. No.: 17/220,265

(22) Filed: Apr. 1, 2021

Related U.S. Application Data
(60) Provisional application No. 63/004,614, filed on Apr. 3, 2020.

(51) Int. Cl. G02B 26/08; B81B 3/00

(52) U.S. Cl. CPC G02B 26/0833; B81B 3/0018; B81B 2201/047

(57) ABSTRACT

A system to spatially modulate light includes an optical reflector to reflect the light. The optical reflector has an actuator that includes a stator and a rotor. The system further includes a controller in communication with the optical reflector. The controller is to drive the optical reflector by applying an excitation voltage between the rotor and the stator. Further, the controller is to apply a baseline voltage between the rotor and the stator, and to detect, during a voltage-off period of the excitation voltage, an induced current induced by the rotor moving relative to the stator. Furthermore, the controller is to determine a current attribute of the induced current and to determine a movement attribute of the optical reflector based on the current attribute.

### CROSS-REFERENCE TO RELATED APPLICATIONS

The present application claims priority to U.S. Provisional Patent Application Serial No. 63/004,614 entitled “Systems to Spatially Modulate Light and Methods of Operating Thereof” and filed on Apr. 3, 2020, the entirety of which is incorporated by reference herein.

### BACKGROUND

Laser scanning projectors and similar devices often employ a collimated laser beam that scans across a flat surface in a raster or scan pattern to form images. These devices employ optical reflectors to deflect the beam to perform the scanning. These optical reflectors may be, or may include, Micro-Electro-Mechanical Systems (“MEMS”) based devices.

### SUMMARY OF EMBODIMENTS

According to an implementation of the present specification, there is provided a method, the method comprising: driving an optical reflector by applying an excitation voltage between a rotor and a stator of an actuator of the optical reflector, the excitation voltage to cause the rotor to move relative to the stator across a range of motion, one or more of the rotor and the stator disposed asymmetrically relative to the range of motion, the excitation voltage being intermittent and having a voltage-on period and a voltage-off period; applying a baseline voltage between the rotor and the stator; detecting during the voltage-off period an induced current induced by the rotor moving relative to the stator; determining a current attribute of the induced current, the current attribute comprising a phase of the induced current; and determining a movement attribute of the optical reflector based on the current attribute.

The driving the optical reflector may comprise driving the optical reflector to oscillate at a frequency f; and the applying the excitation voltage may comprise applying the excitation voltage at a corresponding frequency 2f which is double the frequency f.

The determining the movement attribute may comprise determining a direction of movement of the rotor relative to the stator based on the phase.

The method may further comprise modifying projection of an image to be projected using the optical reflector based on the direction of the movement of the rotor relative to the stator.

The determining the current attribute may further comprise determining a magnitude of the induced current; and the determining the movement attribute may comprise determining a displacement of the rotor relative to the stator based on the magnitude.

The determining the current attribute may further comprise determining whether a magnitude of the induced current is below a given threshold; and the determining the movement attribute may comprise determining a motion status of the rotor relative to the stator based on whether the magnitude of the induced current is below the given threshold.

The applying the excitation voltage between the rotor and the stator of the actuator may comprise applying the excitation voltage between a comb-shaped rotor and a comb-shaped stator of a comb drive actuator.

The applying the excitation voltage between the comb-shaped rotor and the comb-shaped stator may comprise applying the excitation voltage between the comb-shaped rotor and the comb-shaped stator to cause an oscillation of the comb-shaped rotor relative to the comb-shaped stator in the range of motion , one or more of the comb-shaped rotor and the comb-shaped stator may be disposed asymmetrically relative to the oscillation.

The driving the optical reflector may comprise driving a micro-electro-mechanical system (MEMS) based optical reflector.

The method may further comprise converting the induced current into a corresponding induced voltage using a trans-impedance amplifier.

According to another implementation of the present specification there is provided a system to spatially modulate light (e.g., display light from a display), the system comprising: an optical reflector to reflect the light, the optical reflector having an actuator, the actuator comprising a stator and a rotor to move across a range of motion relative to the stator, one or more of the rotor and the stator disposed asymmetrically relative to the range of motion; and a controller in communication with the optical reflector, the controller to: drive the optical reflector by applying an excitation voltage between the rotor and the stator, the excitation voltage to cause the rotor to move relative to the stator, the excitation voltage being intermittent and having a voltage-on period and a voltage-off period; apply a baseline voltage between the rotor and the stator; detect during the voltage-off period an induced current induced by the rotor moving relative to the stator; determine a current attribute of the induced current, the current attribute comprising a phase of the induced current; and determine a movement attribute of the optical reflector based on the current attribute.

To drive the optical reflector the controller may be to drive the optical reflector to oscillate at a frequency f; and to apply the excitation voltage the controller may be to apply the excitation voltage at a corresponding frequency 2f which is double the frequency f.

To determine the movement attribute the controller may be to determine a direction of movement of the rotor relative to the stator based on the phase.

The controller may be further to modify projection of an image to be projected using the optical reflector based on the direction of the movement of the rotor relative to the stator.

To determine the current attribute the controller may be further to determine a magnitude of the induced current; and to determine the movement attribute the controller may be to determine a displacement of the rotor relative to the stator based on the magnitude.

To determine the current attribute the controller may be further to determine whether a magnitude of the induced current is below a given threshold; and to determine the movement attribute the controller may be to determine a motion status of the rotor relative to the stator based on whether the magnitude of the induced current is below the given threshold.

The rotor may comprise a comb-shaped rotor; the stator may comprise a comb-shaped stator; and the actuator may comprise a comb drive actuator.

The comb-shaped rotor may be to oscillate relative to the comb-shaped stator in the range of motion; and one or more of the comb-shaped rotor and the comb-shaped stator may be disposed asymmetrically relative to the oscillation.

The optical reflector may comprise a micro-electro-mechanical system (MEMS) based optical reflector.

The system may further comprise a trans-impedance amplifier in communication with the controller, the trans-impedance amplifier to convert the induced current into a corresponding induced voltage.

### BRIEF DESCRIPTION OF THE DRAWINGS

In the drawings, identical reference numbers identify similar elements or acts. The sizes and relative positions of elements in the drawings are not necessarily drawn to scale. For example, the shapes of various elements and angles are not necessarily drawn to scale, and some of these elements are arbitrarily enlarged and positioned to improve drawing legibility. Further, the particular shapes of the elements as drawn are not necessarily intended to convey any information regarding the actual shape of the particular elements, and have been solely selected for ease of recognition in the drawings.

FIG. 1 shows a schematic top plan representation of an example system to spatially modulate light in accordance with some embodiments of the present disclosure.

FIG. 2 shows a side elevation view of the system of FIG. 1 in accordance with some embodiments of the present disclosure.

FIG. 3 shows a flowchart of an example method of determining a movement attribute of an optical reflector in accordance with some embodiments of the present disclosure.

FIGS. 4A and 4B show schematic representations of example systems that determine movement attributes of the optical reflector of FIG. 3 in accordance with some embodiments of the present disclosure.

FIG. 5 shows a schematic representation of an example system for generating an image in accordance with some embodiments of the present disclosure.

FIG. 6 shows a partial-cutaway perspective view of an example wearable heads-up display in accordance with some embodiments of the present disclosure.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, and the like. In other instances, well-known structures associated with light sources have not been shown or described in detail to avoid unnecessarily obscuring descriptions of the implementations.

As used in this specification and the appended claims, the singular forms “a,” “an,” and “the” include plural referents unless the content clearly dictates otherwise. It should also be noted that the term “or” is generally employed in its broadest sense, that is as meaning “and/or” unless the content clearly dictates otherwise.

Throughout this specification and the appended claims, the term “carries” and variants such as “carried by” are generally used to refer to a physical coupling between two objects. The physical coupling may be direct physical coupling (i.e. with direct physical contact between the two objects) or indirect physical coupling that may be mediated by one or more additional objects. Thus, the term carries and variants such as “carried by” are meant to generally encompass all manner of direct and indirect physical coupling, including without limitation: carried on, carried within, physically coupled to, secured to, and/or supported by, with or without any number of intermediary physical objects therebetween.

The present specification generally relates to spatial light modulators. In particular, the present specification discloses, among other things, methods and systems to determine a movement attribute of an optical reflector of a spatial light modulator. In some examples, the optical reflector includes a rotor movable relative to a stator, and the movement attribute may comprise a direction of movement (e.g., oscillation) of the rotor relative to the stator. In some examples, the movement attribute may comprise a displacement of the rotor relative to the stator of the optical reflector. Determining the movement attribute of the optical reflector is pertinent in some applications of the optical reflector. For example, when the optical reflector is implemented in a laser scanning projection system, the direction of movement of the rotor relative to the stator of the optical reflector may be accounted for to project an image. If the direction of movement of the rotor is not properly accounted for, it may cause abnormalities in the projected image, such as image reversal, and the like. Determination of the direction of movement of the rotor of the optical reflector may also contribute to providing faster start-up and calibration times for the optical reflector, and thus also for scanning laser projector systems which comprise the optical reflector.

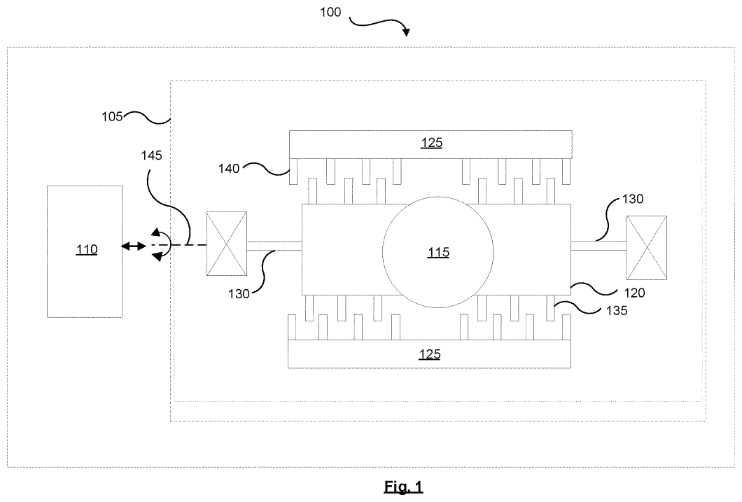

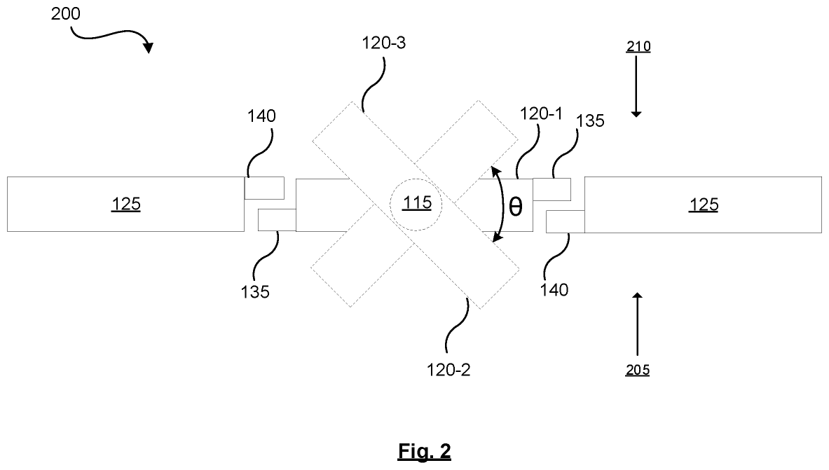

In some examples, a scanning laser projector system may comprise at least two optical reflectors. One of the optical reflectors may comprise a horizontal scan mirror and another optical reflector may comprise a vertical scan mirror, which may scan in orthogonal directions to generate an output of the scanning laser projector system. The horizontal scan mirror may be a fast axis mirror, and the vertical scan mirror may be a slow axis mirror. The fast axis mirror may operate (e.g., scan) at a higher frequency than the slow axis mirror. In some examples, the systems to spatially module light described herein may be used to implement such a fast axis mirror. The nomenclature of “horizontal” and “vertical” is not limiting: The fast-axis mirror and the slow-axis mirror may be in any appropriate orientation which allows a two-dimensional image to be projected, and thus it will be understood that the terms “horizontal” and “vertical” more generally refer to any two axis of orientation that are substantially orthogonal to each other. In other examples, the system to modulate light may comprise an optical reflector having a rotor and a stator. The rotor comprises a mirror. The rotor is movable relative to the stator. The structure and operation of an example optical reflector is explained in detail in relation to FIGS. 1 and 2. In operation, the optical reflector (e.g., fast axis mirror) may be driven by an electrical signal which may cause movement of the rotor relative to the stator.

The optical reflector may be operated in a single pulse operation mode or a dual pulse operation mode. In the single pulse operation mode, a pulse of electrostatic force is applied at a frequency f between the rotor and the stator of the optical reflector to pull the rotor (mirror) towards, or away from a rest position. The rotor (mirror) moves towards the rest position, but swings past due to inertia. As the rotor (mirror) moves, a torsion bar associated with the rotor (mirror) applies a counter force to the rotor, eventually reversing the direction of movement of the rotor (mirror). Then, the rotor (mirror) moves back towards the rest position, but again swings past the rest position due to inertia. The rotor (mirror) then swings back to the position in which the brief pulse of electrostatic force is applied at a specified frequency, denoted “frequency f”.

In the dual pulse operation mode, a first pulse of electrostatic force is applied at a frequency f between the rotor and the stator of the optical reflector to pull the rotor (mirror) towards a rest position. The rotor (mirror) moves towards the rest position but swings past due to inertia. As the rotor (mirror) swings, a second pulse of electrostatic force is applied to pull the rotor (mirror) towards the rest position, reversing the direction of movement of the rotor (mirror). The rotor (mirror) then moves back towards the rest position, but again swings past the rest position due to inertia. The rotor (mirror) then swings back to the position in which the first brief pulse of electrostatic force is applied at the frequency f.

Because of the manner in which the electrostatic pulses are used to cause the rotor to oscillate (as described in greater detail in relation to FIGS. 1 and 2), the pulses applied may not necessarily dictate a direction in which the rotor (mirror) of the optical reflector rotates. That is, for a given pulse, the rotor (mirror) could be rotating in either direction. If not properly accounted for, this could cause abnormalities in the projected image (for example, projected by the scanning laser projector), such as image reversal, and the like.

Further, since the direction of movement (e.g., rotation direction) of the rotor (mirror) at start-up could be different each time, the problem of rotational ambiguity may not be addressed by pre-processing the image to be displayed. This problem may be addressed by starting up the mirror oscillation in the single pulse operation, which is more robust in initial conditions. After the start-up, the operation may be changed to dual pulse operation, which is more power-efficient and has more stable operational range. However, this start-up and conversion process is time consuming, for example the total process may take 200 ms (120 ms for single pulse start-up, and 80 ms for conversion from single pulse operation to dual pulse operation). On the other hand, start-up time when starting in dual pulse operation mode may be much shorter, for example 65 ms. However, the dual pulse operation mode is also subject to rotational ambiguity limitations.

FIG. 1 shows a schematic representation of an example system 100 to spatially modulate light (referred to as “system” henceforth) in accordance with some embodiments. The system 100 comprises an optical reflector 105 and a controller 110. The controller 110 includes one or more processors to execute instructions to provide the functionality described herein, programmable logic (e.g., a field programmable logic array (FPGA) or hardcoded logic to provide the functionality described herein, or a combination thereof. The optical reflector 105 comprises a rotor 120 and stator 125. The optical reflector 105 instead may comprise other arrangements of stators and rotor or a different number of stators.

The rotor 120 may comprise a mirror 115. In some examples, the mirror 115 may comprise a metallic coating, such as but not limited to an aluminum (Al) coating, and the like. The rotor 120 and the stator 125 cooperate to form an actuator for the optical reflector 105. The rotor 120, and thus mirror 115, oscillates about an axis 145 relative to the stator 125 through a pair of torsional bars 130. In some examples, the torsional bars 130 comprise torsional hinges.

The rotor 120 may be a comb-shaped rotor, and the stator 125 may be a comb-shaped stator. The comb-shaped rotor 120 may have projecting structures 135 that project towards the stator 125. The comb-shaped stator 125 had projecting structures 140 that project towards the rotor 120. The projecting structures 135 may interdigitate with the projecting structures 140. The structures 135 may be referred to as rotor combs 135, and the structures 140 may be referred to as stator combs 140. The rotor combs 135 may interdigitate with the stator combs 140 to form comb drives providing an electrostatic actuation mechanism for the optical reflector 105.

From the top view/perspective view of FIG. 1, the rotor 120 and the stator 125 together define a plane when the rotor 120 is in its neutral position (e.g., when the rotor 120 is in its resting position). In some examples, one or more of the rotor 120 and the stator 125 may be disposed asymmetrically relative to the range of motion of the rotor 120. For example, the combs of rotor 120 may also be offset in the out-of-plane direction relative to the combs of stators 125. The rotor 120 and the stator 125 are shown to be comb-shaped rotor and the comb-shaped stator respectively in FIG. 1. However, in other implementations, the rotor 120 and the stator 125 may not be comb-shaped and instead have other shapes.

In operation, the optical reflector 105 is driven by a signal that causes oscillation (partial rotation) of the rotor relative to the stator 125. In some examples, the actuation principle for the optical reflector 105 is electrostatic, where a potential difference is applied between the rotor 120 and the stator 125. As discussed above, the potential difference applied between the rotor 120 and the stator 125 may cause movement of the rotor in the first direction or the second direction.

For example, a voltage may be applied between the rotor combs 135 and the stator combs 140. In this state, the rotor combs 135 and the stator combs 140 interdigitate. The voltage causes the rotor 120 to move back and forth between the two portions of stator 125. This back-and-forth movement of the rotor 120 effectively causes a resonance in the rotor 120, which manifests as rotational oscillation about its axis 145. The oscillation of the rotor 120 causes the mirror 115 to tilt. This manner of moving or oscillating reflector 105 may be described as parametric excitation. In some examples, the voltage may be applied between the rotor 120 and the stator 125 at a particular frequency for the rotor 120 to maintain its resonance.

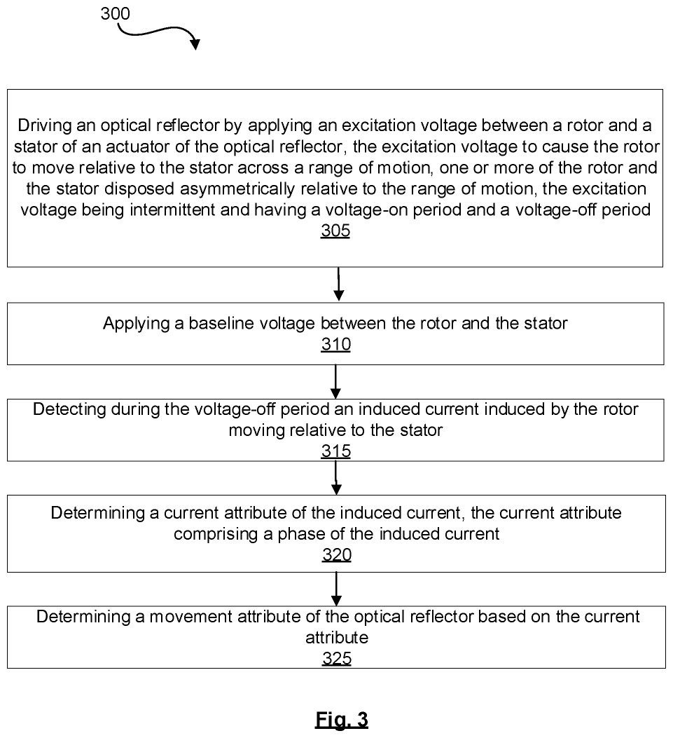

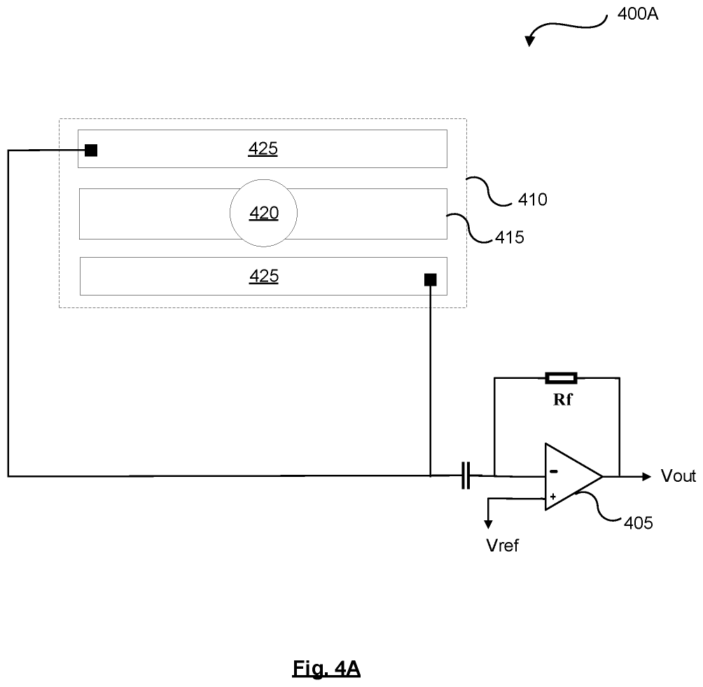

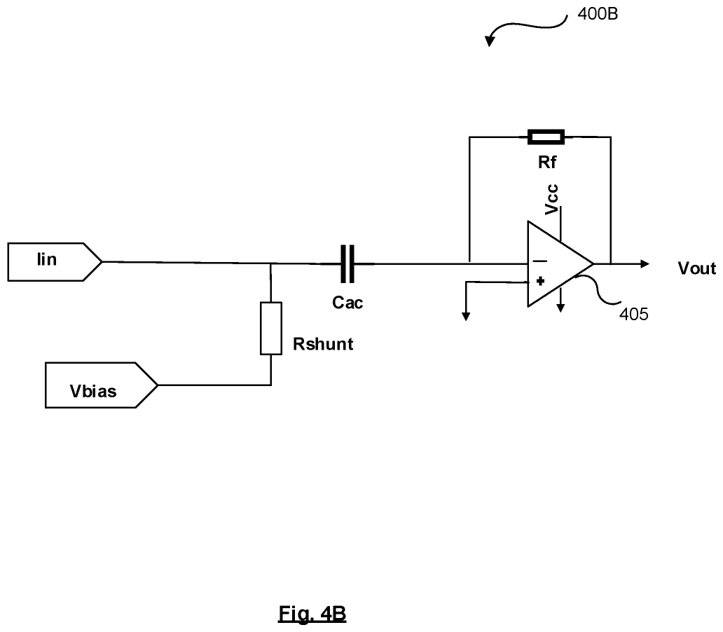

In addition, system 100 may comprise a controller 110 in communication with the optical reflector 105. Controller 110 may control the optical reflector 105. In some examples, the controller 110 may drive the optical reflector by providing excitation signals to the optical reflector 105. Further, the controller 110 may determine a movement attribute (such as direction of movement of the rotor 120 relative to the stator 125) of the optical reflector 105, which is explained in detail below with reference to FIGS. 3 and 4. Also, where the system 100 is integrated into or forms scanning or image projection systems, such as but not limited to a scanning laser projector, the controller 110 may modify projection of an image to be projected using the optical reflector 105 based on the direction of movement of the rotor 120 relative to the stator 125.

In some examples, the controller 110 comprises at least one processor in communication with at least one non-transitory processor-readable medium. The processor-readable medium may comprise instructions to cause the processors to control the optical reflector 105 as described in relation to the methods and systems described herein. Moreover, in some examples the controllers may be free-standing components, while in other examples the controllers may comprise functional modules incorporated into other components of their respective systems. Additionally, the controller 110 may comprise circuitry and components to control the optical reflector 105. For example, the controller 110 may comprise circuitry and components to drive the optical reflector 105 and determine a movement attribute of the optical reflector 105, among other functions. Furthermore, in some examples the controllers or their functionality may be implemented in other ways, including: via Application Specific Integrated Circuits (ASICs), in standard integrated circuits, as one or more computer programs executed by one or more computers (e.g., as one or more programs running on one or more computer systems), as one or more programs executed by on one or more controllers (e.g., microcontrollers), as one or more programs executed by one or more processors (e.g., microprocessors, central processing units, graphical processing units), as firmware, and the like, or as a combination thereof.

In some examples, the system 100 may be implemented as micro-electro-mechanical systems (MEMS) based system. For example, the optical reflector 105 may comprises a MEMS-based optical reflector. As such, the optical reflector 105 may be implemented as a fast axis mirror (horizontal scan mirror) of a scanning laser projector.

Turning now to FIG. 2, a right-side elevation view 200 of the example optical reflector 105 of FIG. 1 is illustrated. As stated above, the application of voltage (e.g., excitation voltage) between the rotor 120 and the stator 125 causes the rotor 120 to move back and forth between the two portions of stator 125. This back-and-forth movement of the rotor 120 causes the resonance in the rotor 120, which manifests as oscillation about axis 145. In other words, due to application of the voltage the rotor 120, and thus mirror 115, oscillates about the axis 145 of oscillation through the pair of torsional bars 130. In FIG. 2, the rotor 120 in its resting position (neutral position) is depicted by 120-1. In an example, when a pulse of electrostatic force (excitation voltage) is applied at a frequency f, for example, to the rotor 120. The rotor 120 oscillates and moves towards the rest position, but swings past due to inertia. As the mirror swings, the torsion bar 130 applies a counter force to the rotor 120, eventually reversing the direction of oscillation of the rotor 120. Then, the rotor 120 oscillates back towards the rest position, but again swings past the rest position due to inertia. Thus, the rotor 120 may swing back and forth between rotor positions 120-2, 120-3 thus defining the range of motion of the rotor. The range of motion of the rotor is depicted by angle θ. The angle θ may be an angle between the two extreme positions (120-2, 120-3) of the rotor in either direction of oscillation.

As illustrated in FIG. 2, the rotor combs 135 can be vertically offset (that is, relative to the out-of-plane direction of FIG. 1) relative to the stator combs 140. The rotor combs 135 being vertically offset relative to the stator combs 140 results in asymmetric disposition of the rotor 120 and the stator 125 relative to the range of motion. Due to the asymmetric disposition, there is a difference in the capacitance associated with the optical reflector 105 when the rotor 120 approaches the stator 125 from a first direction (shown by arrow 205 pointing upwards) and when the rotor 120 approaches the stator 125 from a second direction (shown by arrow 210 pointing downwards) opposite to the first direction. This difference in capacitance may be used to determine the movement attribute of the optical reflector 105. In some examples, the rotor combs 135 can be angularly offset relative to stator combs 140. That is, stator combs 140 could be parallel to each other and in a common plane, whereas at least one of rotor combs 135 can be non-parallel to stator combs 140. Such an angular offset has an asymmetric disposition, such that there is a difference in the capacitance associated with the optical reflector 105 when the rotor 120 approaches the stator 125 from a first direction (shown by arrow 205 pointing upwards), and when the rotor 120 approaches the stator 125 from a second direction (shown by arrow 210 pointing downwards) opposite to the first direction. This difference in capacitance thus may be used to determine the movement attribute of the optical reflector 105.

Turning now to FIG. 3, a flowchart of an example method 300 of determining a movement attribute of an optical reflector is shown in accordance with some embodiments. For example, a movement attribute of the optical reflector 105 may be determined using the method 300. In such an implementation, the movement attribute can include, for example, a direction of movement of the rotor 120 relative to the stator 125 or a displacement of the rotor 120 relative to the stator 125. In some examples, the movement attribute may be determined by the controller 110. In such examples, the controller 110 may perform or control performance of operations described herein in relation to FIG. 3.

Turning now to method 300, at block 305, an optical reflector may be driven by application of an excitation voltage between a rotor and stator of an actuator of the optical reflector. The excitation voltage may have a voltage-on period and a voltage-off period. For example, electro-static pulses of excitation voltage may be applied to drive the optical reflector. In some examples, the excitation voltage may be applied by applying a pulse width modulated (PWM) signal having intermittent voltage-on periods interspersed between voltage-off periods. The excitation voltage may cause the rotor to move relative to the stator across a range of motion. One or more of the rotor and the stator may be disposed asymmetrically relative to the range of motion.

In some examples, the optical reflector may be driven to oscillate at a frequency f, and the excitation voltage may be applied at a corresponding frequency 2f, which is double the frequency f In some examples, the rotor may be a comb-shaped rotor, and the stator may be a comb-shaped stator. For example, the comb-shaped rotor may be rotor 120, and the comb-shaped stator may be stator 125. In such examples, the excitation voltage may be applied between the comb-shaped rotor and the comb-shaped stator of a comb-drive actuator. For example, the excitation voltage may be applied by the controller 110 to the optical reflector 105 through the rotor combs 135 and the stator combs 140. Furthermore, the excitation voltage may be applied between the comb-shaped rotor 120 and the comb-shaped stator 125 to cause an oscillation of the comb-shaped rotor 120 relative to the comb-shaped stator 125 in the range of motion. Moreover, one or more of the comb-shaped rotor 120 and the comb-shaped stator 125 may be disposed asymmetrically relative to the range of motion.

At block 310, a baseline voltage may be applied between the rotor and the stator. For example, a baseline voltage may be applied between the rotor 120 and the stator 125 of the optical reflector 105. The baseline voltage may be applied by the controller 110. The baseline voltage may be applied for the rotor 120 for the optical reflector 105 to maintain the capacitance between the rotor 120 and the stator 125. The changes in the capacitance caused by the motion of rotor 120 relative to stator 125 induces current, e.g., motion-induced current. An attribute of the motion-induced current may be used to determine the movement attribute of the optical reflector 105.

At block 315, the induced current induced by the rotor moving relative to the stator is detected. For example, the induced current may be detected by the controller 110, when the excitation voltage is applied between the rotor 120 and the stator 125 of the optical reflector 105. In some examples, the induced current may be measured, sensed, or the like. The induced current induced by the movement of the rotor relative to the stator is detected during the voltage-off period of the excitation voltage. During the voltage-on period of the excitation voltage, the motion-induced current is masked by current generated due to the excitation voltage. The current generated due to the excitation voltage (also referred to as “voltage-induced current” henceforth) may have much greater amplitude than the motion-induced current, thus masking the actual motion-induced current. During the voltage-off period of the excitation voltage, current generated due to the excitation voltage is zero, thus making it more practicable to detect the motion-induced current.

At block 320, a current attribute of the induced current may be determined. For example, the current attribute may be determined by the controller 110. The current attribute may comprise a phase of the induced current. In some examples, the current attribute may comprise a magnitude of the induced current. In some such examples, it may be determined whether a magnitude of the induced current is below a given threshold. The given threshold may be a particular threshold value which may be indicative of whether the rotor is moving relative to the stator. For example, based on whether the magnitude of the induced current is below the given threshold, a motion status of the rotor relative to the stator may be determined. Thus, the value of the induced current being below the given threshold value, even after application of the excitation voltage, is indicative of that the rotor is not moving relative to the stator, which may be further indicative of a fault or error in operation of the optical reflector. The determination of the magnitude of the induced current may be used as a safety mechanism when the optical reflector stops its operation.

In some examples, to measure the magnitude and phase of the induced current a transimpedance amplifier (TIA) may be used by the controller 110 to convert the induced current into a corresponding induced voltage, which is discussed in greater detail in relation to FIGS. 4A and 4B. In some examples, the magnitude and phase of the induced current relative to the excitation voltage may be measured by using a lock-in amplifier. In some examples, the TIA or the lock-in amplifier may be in communication with or integrated in a controller, for example the controller 110.

At block 325, a movement attribute of the optical reflector may be determined based on the current attribute. For example, the movement attribute of the optical reflector 105 may be determined by the controller 110. In some examples, the movement attribute may comprise a direction of movement of the rotor relative to the stator, which may be determined based on the phase of the induced current. For example, the rotor 120 of the optical reflector 105 oscillates in either the first direction (e.g., clockwise direction) or the second direction (e.g., anti-clockwise direction) about its axis of oscillation. First, when the optical rotor 120 and the mirror 115 oscillates in the first direction, the capacitance associated with the optical reflector 105 is in phase with its angular displacement. But, when the rotor 120 and the mirror 115 oscillates in the second direction (opposite direction), the capacitance associated with the optical reflector is 180-degree out of phase to its angular displacement. Similarly, the motion-induced current has 90-degree phase lead when the rotor 120 and the mirror 115 oscillates in the first direction. When the rotor 120 and the mirror 115 oscillates in the opposite direction, the motion-induced current has 90-degree phase lag with respect to its angular displacement. Hence, the direction of movement of the rotor 120 of the optical reflector 105 may be determined by measuring the phase of the motion-induced current. In some examples, the movement attribute may further comprise a displacement of the rotor relative to the stator, which may be determined based on the magnitude of the induced current. The displacement of the rotor relative to the stator may correspond to a scanning angle of the optical reflector.

Furthermore, in some examples, where the optical reflector is used to project images, the projection of an image may be modified based on the direction of the movement of the rotor relative to the stator, which may be determined based on the phase of the induced current. For example, the optical reflector 105 may be used in the system 500 to project images. The phase of the induced current in the optical reflector 105 may be determined, as stated above in method 300, and based on the determined phase of the induced current, the system 500 may modify projection of the image. The image may be projected by accounting for the direction of the movement of the rotor 120 relative to the stator 125, which may be determined based on the phase of the induced current.

Turning now to FIG. 4A, this figure depicts a schematic representation of an example system 400A for determining a movement attribute of an example optical reflector 410 in accordance with some embodiments. The optical reflector 410 may be similar to the optical reflector 105 and may include a rotor 415 (similar to the rotor 120) having a mirror 420 (similar to the mirror 115), and a stator 425 (similar to the stator 125). For the sake of brevity, some components of the optical reflector such as rotor combs, stator combs, and torsional bars are not shown in FIG. 4A. As depicted, a TIA 405 is employed to convert the induced current into induced voltage. The TIA 405 converts the induced current, which is induced by application of the excitation voltage and motion of the rotor (as stated above), into the corresponding voltage. The TIA 405 may be used to detect the induced current signal in the stators (stator combs) 425 and convert the inducted current into corresponding induced voltage. The system 400A may be in communication with or integrated with a controller which may control operation of the system 400A. In some examples, the controller may comprise the controller 110.

As stated above, in some examples, the rotor of the optical reflector may be driven to oscillate at a frequency f, and the excitation voltage may be applied at a corresponding frequency 2f, which is double the frequency f. When the rotor 415 of the optical reflector 410 oscillates at the frequency f, a signal is induced in the stator 425 with a period of f, since the rotor 415 (and mirror 420) oscillates at the frequency f. When the excitation voltage is applied at a frequency of 2f, the signal in the stator 425 (stator combs) includes a signal induced with frequencies of 2f and its harmonics (4f, 6f, 8f, and the like), as well as the signal induced by motion of the rotor with frequencies of f and its harmonics (2f, 3f, 4f, and the like). Since the excitation voltage (electrostatic pulses) is applied at the frequency of 2f, and not with a frequency f, signals with this frequency f and its harmonics correspond to signals induced by the motion of the optical reflector. Thus, attributes (such as magnitude and phase) of the current induced due to the motion of the rotor 415 may be measured by measuring signals corresponding to the frequency f. The measurement of the current signals corresponding to frequency f may be done by converting the signal to voltage with the TIA 405 as shown in FIG. 4A.

The current induced by the excitation voltage and the motion of the optical reflector may be represented as:

$$i ( t ) = \frac{dC ( t ) V ( t )}{dt} = \frac{dC ( t )}{dt} V ( t ) + C ( t ) \frac{dV ( t )}{dt} \qquad ( 1 )$$

where i(t) represents the current induced by both excitation voltage applied on the optical reflector and the motion of optical reflector; V(t) represents the excitation voltage; and C(t) represents total capacitance including the capacitance of optical reflector. The total capacitance C(t) of the optical reflector may be represented as:

C(t)=Cₚ+Cₘ(t) (2)

where Cp and Cm(t) represent parasitic capacitance of the optical reflector, and the capacitance of optical reflector itself, respectively. In most cases, the parasitic capacitance of the optical reflector does not change over time and may be treated as constant. The capacitance of the optical reflector depends on its angle (e.g., angle of the rotor (mirror) relative to the stator).
So, the current caused by the excitation voltage and motion of the optical reflector may be expressed as follows:

$$i ( t ) = \frac{{dC}_{m} ( θ )}{d θ} \dot{θ} V ( t ) + ( {C}_{p} + {C}_{m} ( t ) ) \frac{dV ( t )}{dt} \qquad ( 3 )$$

where

$$\frac{{dC}_{m} ( θ )}{d θ}$$

denotes the partial deriviative of the optical reflector capacitance with respect to its angle; and \dot{θ} represents its angular velocity.

The current induced by the excitation voltage is at the same frequency as oscillation frequency of the optical reflector, and is represented by the 2^{nd} term in Eq. 3, i.e.,

$$( {C}_{p} + {C}_{m} ( t ) ) \frac{dV ( t )}{dt} .$$

The 1^{st} term i.e.,

$$\frac{{dC}_{m} ( θ )}{d θ} \dot{θ} V ( t )$$

in Eq. 3 represents the motion-induced current.

Since frequency of the excitation voltage applied to the optical reflector is known, the motion-induced current is measured at one particular frequency (and its harmonics). Thus, by locking into one of those frequencies, the magnitude and phase of the motion-induced current may be measured using a quadrature demodulator or IQ demodulator, which provides the in-phase and quadrature components of the measured current at one of the harmonics. The magnitude of the current is proportional to the square root of the sum of the in-phase and quadrature components squared, and the phase is equal to the arctan of the in-phase and quadrature components, where its magnitude and phase represent the opening angle and the deviation from the resonance of the optical reflector, respectively.

The magnitude of the current may be represented as:

Magnitude=\sqrt{i²+q²},

The phase of the current may be represented as:

$$Phase = {tan}^{- 1} ( \frac{q}{i} )$$

where i represents the in-phase component of the current, and q represents the quadrate component of the current.

In some examples, the TIA 405 may be used in conjunction with a quadrature demodulator. In some such examples, a filter stage may be used with the TIA 405. Since the induced current needs to be measured at one particular frequency, the filter stage may be implemented with a high-order low pass filter (LPF) or band pass filter (BPF) to improve signal to noise ratio (SNR). Furthermore, in some examples, samples of the motion-induced current, and the discrete samples may be multiplied by reference signals, sine and cossine, at a chosen frequency, and may be filtered to extract the magnitude and phase information that may be used for determining the movement attribute (e.g., displacement of the rotor, and direction of movement of the rotor) of the optical reflector.

Turning now to FIG. 4B, which shows another example system 400B that employs TIA 405. Stators 425 of the optical reflector 410 may be DC-coupled to DC bias voltage (Vbias) through the shunt coupling resistor (Rshunt), and AC-coupled to the inverting input (Iin) of TIA 405 through an AC-coupling capacitor (Cac). As stated above, because the voltage-induced current is much greater than the motion-induced current, the motion-induced current may be measured, while the voltage-induced current is zero. In other words, the motion-induced current may be measured when the excitation voltage is off e.g., during the voltage-off period of the excitation voltage. Since V(t) (in equation 3 above) represents the potential difference between the rotor and stators of the optical reflector, V(t) is the same as the DC bias voltage (Vbias) when excitation voltage is Off (during the voltage-off period of the excitation voltage).

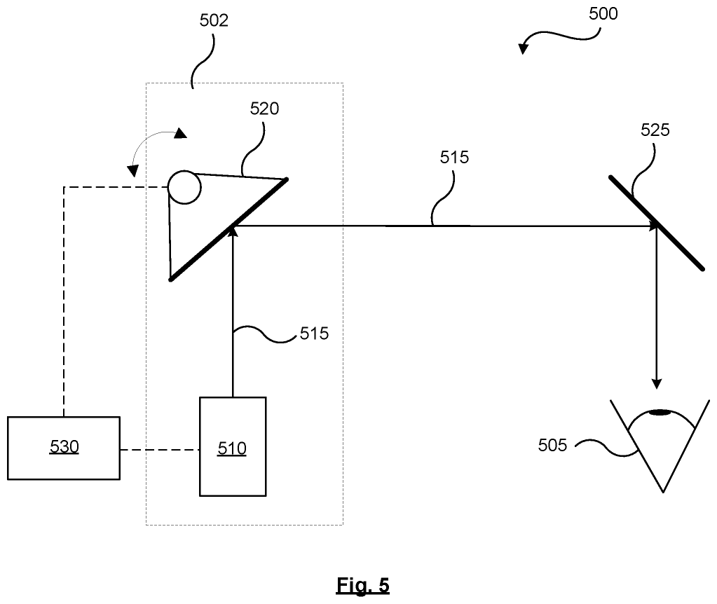

Turning now to FIG. 5, a schematic representation is shown of an example system 500, which may implement the system 100. System 500 may be used to form or project an image viewable by an eye 505 of a viewer. System 500 may also be referred to or described as an image projection device (e.g., scanning laser projector), a display device, a display system, or a display. The viewer may also be described as a user of system 500. System 500 may comprise a light engine 502 to generate a beam of output light 515 (that is, display light). In some examples, light engine 502 may comprise a light source 510 to generate output light 515. Light source 510 may comprise at least one laser, at least one light emitting diode, and the like. Light engine 502 may also comprise a spatial modulator 520 to receive output light 515 from light source 510. In some examples, the spatial modulator 520 may comprise a movable reflector, a micro-electro-mechanical system (MEMS), a digital micromirror device (DMD), and the like. In some examples, the spatial modulator 520 may comprise the optical reflector 105. In some examples, spatial modulator 520 may include both a fast-axis mirror and a slow axis mirror.

Furthermore, system 500 may comprise a display optic 525 to receive output light 515 from the light engine 502 and direct the output light towards the eye 505 of the viewer to form an image viewable by the user. Moreover, in some examples, system 500 may be a part of or incorporated into a wearable heads-up display (WHUD). Such a heads-up display may have different designs or form factors, such as the form factor of eyeglasses, as is described in greater detail in relation to FIG. 5. In examples where system 500 is in the form factor of glasses, display optic 525 may be on or in a lens of the glasses.

In addition, system 500 comprises a controller 530 in communication with the light engine 502. Controller 530 may control the light engine 502 to project an image. In some examples, the image to be projected may be a still image, a moving image or video, an interactive image, a graphical user interface, and the like. In some examples, the controller 530 may comprise the controller 110. In such examples, the controller 530 may control the optical reflector 105 (which may be implemented as spatial modulator 520 or as a component of spatial modulator 520) in a manner as described above in relation to FIGS. 1, 2, 3,4A, and 4B.

In some examples, the controllers described herein such as controller 530 may comprise at least one processor in communication with at least one non-transitory processor-readable medium. The processor-readable medium may comprise instructions to cause the processors to control the light source and the spatial modulator as described in relation to the methods and systems described herein. Moreover, in some examples the controllers may be free-standing components, while in other examples the controllers may comprise functional modules incorporated into other components of their respective systems. Furthermore, in some examples the controllers or their functionality may be implemented in other ways, including: via Application Specific Integrated Circuits (ASICs), in standard integrated circuits, as one or more computer programs executed by one or more computers (e.g., as one or more programs running on one or more computer systems), as one or more programs executed by on one or more controllers (e.g., microcontrollers), as one or more programs executed by one or more processors (e.g., microprocessors, central processing units, graphical processing units), as firmware, and the like, or as a combination thereof.

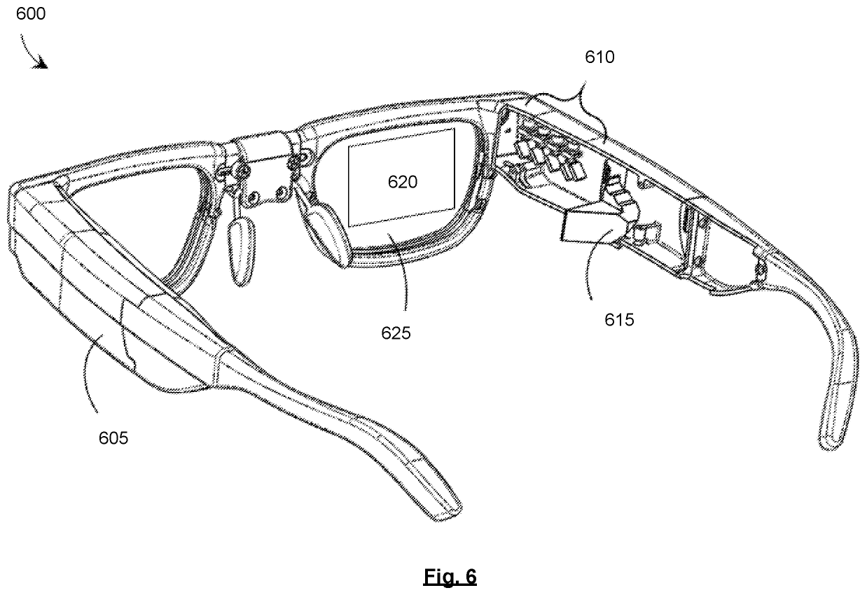

Turning now to FIG. 6, a partial-cutaway perspective view of an example wearable heads-up display (WHUD) 600 is shown. WHUD 600 includes a support structure 605 that in use is worn on the head of a user and has the general form factor and appearance of an eyeglasses (e.g., sunglasses) frame. Eyeglasses or sunglasses may also be generically referred to as “glasses”. Support structure 605 may carry components of a system to display an image, such as system 100, or system 500. For example, the light source module may be received in a space 610 in a side arm of support structure 605. In other examples, one or more of the image projection and output light adjustment system components or systems described herein may be received in or carried by support structure 605.

The spatial modulator of the systems described herein may be received in or be part of component 615 of support structure 605. The spatial modulator in turn may direct the output light onto a display optic 620 carried by a lens 625 of support structure 605. Moreover, in some examples, the display optic 620 may be similar in structure or function to display optic 525. Moreover, in some examples display optic 620 may comprise an optical incoupler, a waveguide, and an optical outcoupler.

It is contemplated that method 300 and the other methods described herein may be performed by system 100, system 500, WHUD 600, and the other systems and devices described herein. It is also contemplated that method 300 and the other methods described herein may be performed by systems or devices other than the systems and devices described herein. In addition, it is contemplated that system 100, system 500, WHUD 600, and the other systems and devices described herein may have the features and perform the functions described herein in relation to method 300 and the other methods described herein. Moreover, system 100, system 500, WHUD 600, and the other systems and devices described herein may have features and perform functions other than those described herein in relation to method 300 and the other methods described herein. In addition, while some of the examples provided herein are described in the context of scanning laser projectors and WHUDs, it is contemplated that the functions and methods described herein may be implemented in or by display systems or devices which may not be WHUDs.

Throughout this specification and the appended claims, infinitive verb forms are often used. Examples include, without limitation: “to drive,” “to apply,” “to detect,” and the like. Unless the specific context requires otherwise, such infinitive verb forms are used in an open, inclusive sense, that is as “to, at least, drive” to, at least, apply,” “to, at least, detect,” and so on.

The above description of illustrated example implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. Moreover, the various example implementations described herein may be combined to provide further implementations.

In general, in the following claims, the terms used should not be construed to limit the claims to the specific implementations disclosed in the specification and the claims but should be construed to include all possible implementations along with the full scope of equivalents to which such claims are entitled. Accordingly, the claims are not limited by the disclosure.

1. A method comprising:
driving an optical reflector by applying an excitation voltage between a rotor and a stator of an actuator of the optical reflector, the excitation voltage to cause the rotor to move relative to the stator across a range of motion and being intermittent and having a voltage-on period and a voltage-off period, and wherein at least one of the rotor and the stator is disposed asymmetrically relative to a range of motion;
applying a baseline voltage between the rotor and the stator;
detecting during the voltage-off period an induced current induced by the rotor moving relative to the stator;
determining a current attribute of the induced current, the current attribute comprising a phase of the induced current; and
determining a movement attribute of the optical reflector based on the current attribute.

2. The method of claim 1, wherein:
driving the optical reflector comprises driving the optical reflector to oscillate at a frequency f; and
applying the excitation voltage comprises applying the excitation voltage at a frequency 2*f.

3. The method of claim 1, wherein:
the movement attribute comprises a direction of movement of the rotor relative to the stator based on the phase.

4. The method of claim 3, further comprising:
modifying projection of an image via the optical reflector based on the direction of the movement of the rotor relative to the stator.

5. The method of claim 1, wherein:
the current attribute comprises a magnitude of the induced current; and
the movement attribute comprises a displacement of the rotor relative to the stator based on the magnitude.

6. The method of claim 1, wherein:
determining the current attribute further comprises determining whether a magnitude of the induced current is below a given threshold; and
determining the movement attribute comprises determining a motion status of the rotor relative to the stator based on whether the magnitude of the induced current is below the given threshold.

7. The method of claim 1, wherein applying the excitation voltage between the rotor and the stator of the actuator comprises applying the excitation voltage between a comb-shaped rotor and a comb-shaped stator of a comb drive actuator.

8. The method of claim 7, wherein applying the excitation voltage between the comb-shaped rotor and the comb-shaped stator comprises applying the excitation voltage between the comb-shaped rotor and the comb-shaped stator to cause an oscillation of the comb-shaped rotor relative to the comb-shaped stator in the range of motion, one or more of the comb-shaped rotor and the comb-shaped stator being offset from an axis of oscillation.

9. The method of claim 1, wherein the optical reflector is a micro-electro-mechanical system (MEMS)-based optical reflector.

10. The method of claim 1, further comprising:
converting the induced current into a corresponding induced voltage using a trans-impedance amplifier.

11. A system to project images by spatially modulating light, the system comprising:
an optical reflector to reflect the light, the optical reflector having an actuator comprising a stator and a rotor to move across a range of motion relative to the stator; and
a controller in communication with the optical reflector, the controller to:
drive the optical reflector by applying an excitation voltage between the rotor and the stator, the excitation voltage to cause the rotor to move relative to the stator, the excitation voltage being intermittent and having a voltage-on period and a voltage-off period;
apply a baseline voltage between the rotor and the stator;
detect, during the voltage-off period, an induced current induced by the rotor moving relative to the stator;
determine a current attribute of the induced current, the current attribute comprising a phase of the induced current; and
determine a movement attribute of the optical reflector based on the current attribute.

12. The system of claim 11, wherein:
the controller is to drive the optical reflector to oscillate at a frequency f; and
the controller is to apply the excitation voltage at a frequency 2*f.

13. The system of claim 11, wherein:
the controller is to determine the movement attribute as a direction of movement of the rotor relative to the stator based on the phase.

14. The system of claim 13, wherein the controller is further to modify projection of an image by the optical reflector based on the direction of the movement of the rotor relative to the stator.

15. The system of claim 11, wherein the controller is further to:
determine the current attribute as a magnitude of the induced current; and
the controller is to determine the movement attribute as a displacement of the rotor relative to the stator based on the magnitude.

16. The system of claim 11, wherein the controller is to:
determine the current attribute by determining whether a magnitude of the induced current is below a given threshold; and
determine the movement attribute by determining a motion status of the rotor relative to the stator based on whether the magnitude of the induced current is below the given threshold.

17. The system of claim 11, wherein:
the rotor comprises a comb-shaped rotor;
the stator comprises a comb-shaped stator; and
the actuator comprises a comb drive actuator.

18. The system of claim 17, wherein:
the comb-shaped rotor is configured to oscillate relative to the comb-shaped stator in the range of motion; and
at least one of the comb-shaped rotor and the comb-shaped stator is disposed asymmetrically relative to the oscillation of the comb-shaped rotor.

19. The system of claim 11, further comprising:
a trans-impedance amplifier in communication with the controller, the trans-impedance amplifier to convert the induced current into a corresponding induced voltage.

20. The system of claim 11, further comprising:
a light engine to generate the light;
a lens to receive the light reflected by the optical projector; and
a support structure for the optical reflector, the light engine, and the lens, the support structure having an eyeglass form factor.
